(19) United States
(12) Patent Application Publication
(10) Pub. No.: US 2026/0338894 A1
(43) Pub. Date: Oct. 29, 2026

(54) IMAGING METHOD FOR MAGNETIC RESONANCE IMAGING SYSTEM AND MAGNETIC RESONANCE IMAGING SYSTEM

(71) Applicant: GE Precision Healthcare LLC, Waukesha, WI (US)

(72) Inventors: Hanbei Zhang, Beijing (CN); Yongchuan Lai, Beijing (CN); Xiaocheng Wei, Beijing (CN); Bin Xie, Beijing (CN); Teresa Weng, Beijing (CN)

(21) Appl. No.: 19/659,922

(22) Filed: Apr. 27, 2026

(30) Foreign Application Priority Data
Apr. 27, 2025 (CN) 202510537250.7

(51) Int. Cl. G01R 33/483; G01R 33/56

(52) U.S. Cl. CPC G01R 33/4838; G01R 33/5607

(57) ABSTRACT

Embodiments of the present application provide an imaging method for a magnetic resonance imaging system and a magnetic resonance imaging system. The method includes: executing a first pulse sequence, wherein the first pulse sequence is used to saturate a signal corresponding to a saturation band in a current scanning layer surface; and executing a second pulse sequence, wherein the second pulse sequence is used to acquire magnetic resonance imaging data from a region of interest of the current scanning layer surface.

### CROSS-REFERENCE TO RELATED APPLICATIONS

This application is based on and claims priority to Chinese Patent Application No. 202510537250.7, filed on Apr. 25, 2025, the entire contents of which is herein incorporated by reference.

### TECHNICAL FIELD

Embodiments of the present application relate to the technical field of medical devices, and in particular to an imaging method for a magnetic resonance imaging system and a magnetic resonance imaging system.

### BACKGROUND

Magnetic resonance (MR) imaging systems are widely used in the field of medical diagnosis. A magnetic resonance imaging system generally has a main magnet, a gradient amplifier, a radio-frequency amplifier, a gradient coil, a transmit chain module, a transmit/receive coil, a receive chain module, etc. The transmit chain module generates a pulse signal and transmits the same to the transmit/receive coil; the transmit/receive coil generates a radio-frequency excitation signal to excite a scanned subject to generate a magnetic resonance signal; and after the excitation ends, by means of spatial encoding, the transmit/receive coil acquires the magnetic resonance signal, and fills the magnetic resonance signal into a k-space so that a medical image is reconstructed.

During magnetic resonance imaging, gradient nonlinearity and spatial variation of a magnetic field cause a high-brightness signal located outside a region of interest (field of view) to be picked up by a coil, which introduces an Annefact artifact in a reconstructed image. The Annefact artifact often appears as a bright feathery line that may span the region of interest, leading to difficulty in diagnosis.

Spatial saturation technology is a commonly used technology in magnetic resonance imaging, in which a preset region (also referred to as a saturation band) is selectively excited by applying a saturation pulse, so that a tissue signal within the preset region reaches a saturated state (i.e., the magnetic resonance signal is weakened or even disappears due to an insufficient magnetization vector). In a subsequent formal imaging data acquisition process, the preset region cannot generate a valid signal due to signal saturation, thereby preventing an artifact generated due to signal interference of the preset region.

### SUMMARY OF THE INVENTION

The inventors have found that, in an imaging data acquisition process, selection of a scanning layer surface is implemented by applying a gradient pulse in a layer selection direction, and then image data of the selected scanning layer surface is acquired. Therefore, in the imaging data acquisition process, spatial variation of a main magnetic field (B0) and linearity of a gradient in the layer selection direction have an influence on generation of a high-brightness signal.

In a conventional spatial saturation technology, a gradient is applied in one gradient direction along with a saturation pulse in order to saturate a signal within a region (a saturation band) corresponding to the gradient. The gradient direction is a direction different from the layer selection direction. In other words, the conventional spatial saturation technology expects to perform uniform signal saturation for all scanning layer surfaces within the entire scanning range.

The gradient direction is different from the layer selection direction, gradient linearity of the gradient direction is different from gradient linearity of the layer selection direction, and a frequency component of a region (also referred to as an Annefact source region) causing a high-brightness signal is quite complex. Therefore, if uniform signal saturation is performed for all scanning layer surfaces, a signal in the region needs to be saturated by using a saturation pulse with a quite large bandwidth and a quite large flip angle. However, the existing hardware capability is difficult to implement.

To resolve at least one of the aforementioned problems, embodiments of the present application provide an imaging method for a magnetic resonance imaging system and a magnetic resonance imaging system.

According to an aspect of the embodiments of the present application, an imaging method for a magnetic resonance imaging system is provided, the method comprising: executing a first pulse sequence, wherein the first pulse sequence is used to saturate a signal corresponding to a saturation band in a current scanning layer surface; and executing a second pulse sequence, wherein the second pulse sequence is used to acquire magnetic resonance imaging data from a region of interest of the current scanning layer surface.

According to an aspect of the embodiments of the present application, a magnetic resonance imaging system is provided, the system comprising: a scanning unit; and a controller, which is configured to control the scanning unit to execute the aforementioned imaging method.

One of the beneficial effects of the embodiments of the present application is that: The magnetic resonance imaging system executes a first pulse sequence that is used to saturate a signal corresponding to a saturation band in a current scanning layer surface, and then executes a second pulse sequence that is used to acquire magnetic resonance imaging data from a region of interest of the current scanning layer surface. In other words, only the signal corresponding to the saturation band in the current scanning layer surface is saturated before the magnetic resonance imaging data of the region of interest is acquired. Compared with performing uniform signal saturation for all scanning layer surfaces, the range of a saturation band in a single scanning layer surface is smaller, and a signal corresponding to the saturation band has a limited frequency component, so that requirements for a bandwidth and a flip angle of a saturation pulse can be reduced, thereby reliably preventing an Annefact artifact and facilitating hardware implementation.

With reference to the following description and drawings, specific implementations of the embodiments of the present application are disclosed in detail, and the way in which the principles of the embodiments of the present application can be employed are illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of an imaging method for a magnetic resonance imaging system according to an embodiment of the present application;

FIG. 3 is a schematic diagram of a conventional manner of applying a saturation band;

FIG. 4 is a schematic diagram of a manner of applying a saturation band according to an embodiment of the present application;

FIG. 5 is a schematic diagram of a saturated subject of each scanning layer surface according to an embodiment of the present application; and

FIG. 6 is a schematic diagram of a first pulse sequence and a second pulse sequence according to an embodiment of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc., are used to distinguish different elements, but do not represent a spatial arrangement or temporal order, etc., of these elements, and these elements should not be limited by these terms. The term “and/or” includes any and all combinations of one or more associated listed terms. The terms “comprise”, “include”, “have”, etc., refer to the presence of described features, elements, components, or assemblies, but do not exclude the presence or addition of one or more other features, elements, components, or assemblies.

In the embodiments of the present application, the singular forms “a”, “the”, etc., include plural forms, and should be broadly construed as “a type of” or “a class of” rather than being limited to the meaning of “one”. In addition, the term “the” should be construed as including both the singular and plural forms, unless otherwise specified in the context. In addition, the term “according to” should be construed as “at least in part according to . . . ” and the term “based on” should be construed as “at least in part based on . . . ”, unless otherwise specified in the context.

In the embodiments of the present application, the term “scanned subject” may be equivalently replaced with “subject”, “subject to be scanned”, “subject being scanned”, “patient”, “subject of study”, or the like, and the “scanned subject” may be a living being such as a human being or an animal, or an inanimate object.

In the embodiments of the present application, the term “include/comprise” when used herein refers to the presence of features, integrated components, steps, or assemblies, but does not preclude the presence or addition of one or more other features, integrated components, steps, or assemblies.

The features described and/or illustrated for one implementation may be used in one or more other implementations in the same or similar way, be combined with features in other implementations, or replace features in other implementations.

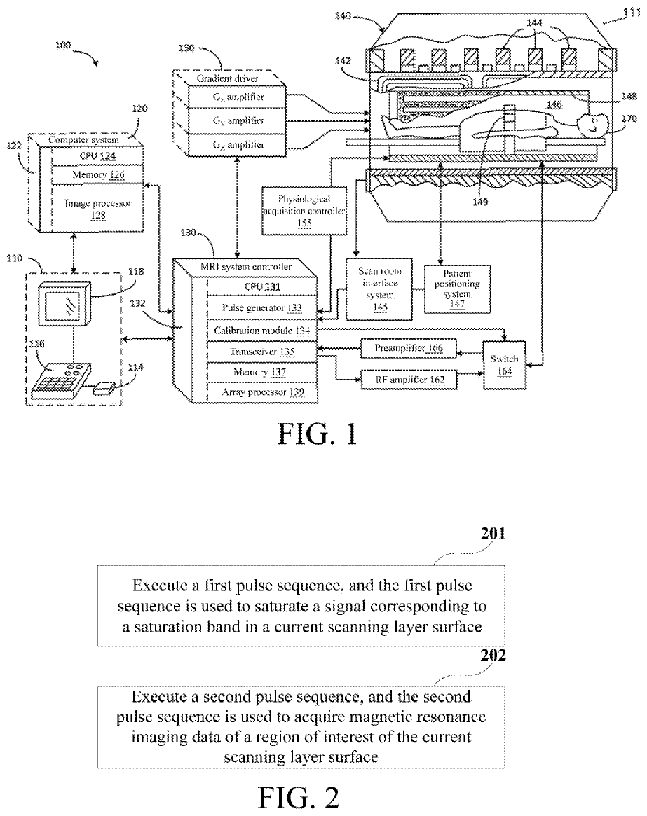

For ease of understanding, FIG. 1 shows a magnetic resonance imaging (MRI) system 100 according to some embodiments of the present application.

As shown in FIG. 1, the MRI system 100 includes a scanning unit 111. The scanning unit 111 is configured to perform a magnetic resonance scan of a scanned subject (e.g., a human body) 170 to generate image data of a region of interest of the scanned subject 170, wherein the region of interest may be a predetermined anatomical site or anatomical tissue.

The operation of the MRI system 100 is controlled by an operator workstation 110. The operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120 that enables an operator to control the generation and display of images on the display 118. The computer system 120 includes various components that communicate with one another via an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by medical imaging functions implemented in the CPU 124. The computer system 120 may be connected to an archive media device, a persistent or backup memory, or a network. The computer system 120 may be coupled to and communicate with a separate MRI system controller 130.

The MRI system controller 130 includes a set of components that communicate with one another via an electrical and/or data connection module 132. The connection module 132 may employ a direct wired connection, a fiber optic connection, a wireless communication link, etc. The MRI system controller 130 may include a CPU 131, a sequence pulse generator (also known as pulse generator) 133 communicating with the operator workstation 110, a calibration module 134 used to calibrate a medical imaging system, a transceiver (also known as RF transceiver) 135, a memory 137, and an array processor 139.

In some embodiments, the sequence pulse generator 133 may be integrated into a resonance assembly 140 of the scanning unit 111 of the MRI system 100. The MRI system controller 130 may receive a command from the operator workstation 110, and is coupled to the scanning unit 111 to indicate an MRI scanning sequence to be executed during an MRI scan, so as to be used to control the scanning unit 111 to execute the flow of the aforementioned magnetic resonance scan. The MRI system controller 130 is further coupled to a gradient driver system (also known as gradient driver) 150 and communicates therewith, and the gradient driver system is coupled to a gradient coil assembly 142 to generate a magnetic field gradient during an MRI scan.

The sequence pulse generator 133 may further receive data from a physiological acquisition controller 155 that receives signals from a plurality of different sensors (e.g., electrocardiogram (ECG) signals from electrodes attached to a patient, etc.), the sensors being connected to a scanned subject or patient 170 undergoing an MRI scan. The sequence pulse generator 133 is coupled to and communicates with a scan room interface system 145 that receives signals from various sensors associated with the state of the resonance assembly 140. The scan room interface system 145 is further coupled to a patient positioning system 147 and communicates therewith, and the patient positioning system 147 sends and receives signals to control a patient table (e.g., an examination table) to move to a desired position for an MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in the gradient coil assembly 142, so as to generate a magnetic field gradient used to spatially encode an MR signal during an MRI scan. The gradient coil assembly 142 is disposed within the resonance assembly 140, and the resonance assembly further includes a superconducting magnet having a superconducting coil 144 that, in operation, provides a static uniform longitudinal magnetic field B₀ throughout a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146.The resonance assembly 140 may further include an RF surface coil 149 for imaging different anatomical structures of a patient undergoing an MRI scan. The RF body coil 148 and the RF surface coil 149 may be configured to operate in a transmit and receive mode, a transmit mode, or a receive mode.

The x direction may also be referred to as a frequency encoding direction or a kx direction in the k-space, the y direction may be referred to as a phase encoding direction or a ky direction in the k-space, and the z direction may be referred to as a layer surface (slice) selection (layer selection) direction or layer direction. Gₓ can be used for frequency encoding or signal readout or data readout, and is generally referred to as a frequency encoding gradient or a readout gradient. G_{y} may be used for phase encoding, and is generally referred to as a phase encoding gradient. G_{z} can be used for slice (layer, or layer surface) position selection to acquire k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses amplified by an RF amplifier 162, and provides the same to the RF body coil 148 by means of a transmit/receive switch (also known as a T/R switch or a switch) 164.

As described above, the RF body coil 148 and the RF surface coil 149 may be used to transmit RF excitation pulses and/or receive obtained MR signals from a patient undergoing an MRI scan. The MR signals emitted by excited nuclei in the patient of the MRI scan may be sensed and received by the RF body coil 148 or the RF surface coil 149 and sent back to a preamplifier 166 by means of the T/R switch 164. The T/R switch 164 may be controlled by a signal from the sequence pulse generator 133 to electrically connect the RF amplifier 162 to the RF body coil 148 in the transmit mode and to connect the preamplifier 166 to the RF body coil 148 in the receive mode. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored in the memory 137 for post-processing as a raw k-space data array. A reconstructed magnetic resonance image may be obtained by transforming/processing the stored raw k-space data.

In some embodiments, the MR signals sensed and received by the RF body coil 148 or the RF surface coil 149 and amplified by the preamplifier 166 are demodulated, filtered, and digitized in a receiving portion of the transceiver 135, and transmitted to the memory 137 in the MRI system controller 130. For each image to be reconstructed, the data is rearranged into separate k-space data arrays, and each of said separate k-space data arrays is input to the array processor 139, the array processor being operated to transform the data into an array of image data by Fourier transform.

The array processor 139 uses transform methods, most commonly Fourier transform, to create images from received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 1 is intended for illustration. Suitable MRI systems may include more, fewer, and/or different components.

The MRI system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, medical imaging, etc. For example, the storage medium may store a program used to implement the magnetic resonance imaging method according to the embodiments of the present application. The described storage medium may include, for example, a ROM, a floppy disk, a hard disk, an optical disk, a magneto-optical disk, a CD-ROM, or a non-volatile memory card.

The aforementioned “imaging sequence” (also referred to below as a scanning sequence or a pulse sequence) refers to a combination of pulses having specific amplitudes, widths, directions, and time sequences applied when a magnetic resonance imaging scan is executed. These pulses may typically include, for example, radio-frequency pulses and gradient pulses. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Typically, a plurality of scan sequences may be preset in the magnetic resonance system, so that a sequence suitable for clinical examination requirements can be selected. The clinical examination requirements may include, for example, an imaging site, an imaging function, an imaging effect, and the like.

In addition, the aforementioned gradient field can be considered as being oriented both in a physical plane and by the logical axis. In a physical sense, these fields are oriented orthogonally to each other to form a coordinate system, and the coordinate system can be rotated by appropriately manipulating a pulse current applied to an individual gradient field coil.

Thanks to the gradient system, magnetic resonance imaging can be implemented in any direction. Conventional anatomical sites may be scanned using conventional orthoaxial (tri-azimuthal) scans: transverse (TRA) or axial (AX), sagittal (SAG), and coronal (COR) scans. Some special complex sites may be scanned using an oblique scan, for example, a short-axis, four-chamber view is used for a cardiac scan.

In an orthoaxial scan, a physical gradient generated by a gradient amplifier can be configured with respect to an imaging system, so that a physical axis aligns/coincides with the logical axis when imaging is performed in an axial reference plane, a sagittal reference plane, and a coronal reference plane. For example, for axial imaging, coronal imaging, or sagittal imaging, the G_{z} amplifier can be configured to generate a layer surface selection gradient, the G_{y} amplifier can be configured to generate a phase encoding gradient, and the Gₓ amplifier can be configured to generate a frequency encoding gradient.

When an oblique scan is performed, the logical axis-based coordinate system is rotated by a certain angle relative to the physical axis-based coordinate system. In this case, the layer surface selection gradient, the frequency encoding gradient, and the phase encoding gradient need to be defined in the logical axis-based coordinate system. The layer surface selection gradient determines a slice of tissue or anatomical structure to be imaged in a patient. Therefore, a layer surface selection gradient field can be applied simultaneously with a selective radio frequency excitation pulse to excite spin volumes in oblique layer surfaces precessing at the same frequency. A layer surface thickness is determined by a bandwidth of the radio frequency excitation pulse and gradient strength in an entire field of view.

Description is made below in conjunction with the embodiments.

An embodiment of the present application provides an imaging method for a magnetic resonance imaging system.

FIG. 2 is a schematic diagram of an imaging method for a magnetic resonance imaging system according to an embodiment of the present application. As shown in FIG. 2, the method includes:

Step 201: executing a first pulse sequence, wherein the first pulse sequence is used to saturate a signal corresponding to a saturation band in a current scanning layer surface; and

Step 202: executing a second pulse sequence, wherein the second pulse sequence is used to acquire magnetic resonance imaging data from a region of interest of the current scanning layer surface.

According to the aforementioned embodiment, the magnetic resonance imaging system executes a first pulse sequence that is used to saturate a signal corresponding to a saturation band in a current scanning layer surface, and then executes a second pulse sequence that is used to acquire magnetic resonance imaging data from a region of interest of the current scanning layer surface. In other words, only the signal corresponding to the saturation band in the current scanning layer surface is saturated before the magnetic resonance imaging data of the region of interest is acquired. Compared with performing uniform signal saturation for all scanning layer surfaces, the range of a saturation band in a single scanning layer surface is smaller, and a signal corresponding to the saturation band has a limited frequency component, so that requirements for a bandwidth and a flip angle of a saturation pulse can be reduced, thereby reliably preventing an Annefact artifact and facilitating hardware implementation.

FIG. 3 is a schematic diagram of a conventional manner of applying a saturation band. As shown in FIG. 3, an S-I direction is a B0 magnetic field direction (a main magnetic field direction), and the S-I direction may also be referred to as a traveling direction of a scanned subject in the magnetic resonance imaging system, a moving direction of a bedplate, etc. In an example in which the scanned subject is a human body, the S-I direction is a head-foot direction of the human body.

As shown in FIG. 3, in the magnetic resonance imaging system, the B0 magnetic field has high uniformity in an isocenter region of a magnet. However, at a position far away from the center, such as an edge of the magnet, linearity of the B0 magnetic field is relatively low, and magnetic field strength exhibits irregular changes (in FIG. 3, a star-shaped intensity region represents a region in which the magnetic field strength exhibits irregular changes, and this region is an Annefact source region).

As described above, in the conventional saturation technology, uniform signal saturation is performed for all scanning layer surfaces within the scanning range. The dashed-line box in FIG. 3 shows a position of a saturation band 301 corresponding to all scanning layer surfaces, and the saturation band 301 covers Annefact source regions of all scanning layer surfaces. It is expected to simultaneously saturate spins of all atomic nuclei in the saturation band 301 by using a saturation pulse.

However, since a spin resonance frequency of an atomic nucleus in the star-shaped intensity region covers a quite wide range, if effective saturation is to be performed, the saturation pulse needs to have a huge bandwidth and flip angle, which is difficult to implement by current hardware.

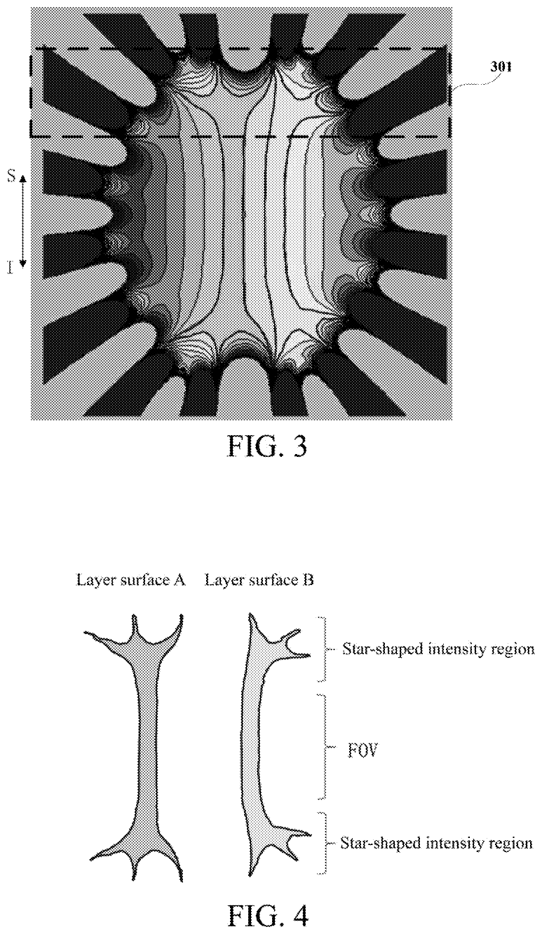

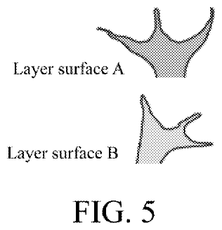

FIG. 4 is a schematic diagram of a manner of applying a saturation band according to an embodiment of the present application. FIG. 5 is a schematic diagram of a saturated subject of each scanning layer surface according to an embodiment of the present application.

As shown in FIG. 4, in this embodiment of the present application, signal saturation is performed for a single scanning layer surface. Taking a scanning layer surface A and a scanning layer surface B as an example, the field of view (FOV, i.e., the region of interest) is arranged at a position close to the center of the magnetic field, and since the B0 magnetic field has good uniformity, imaging quality can be ensured.

As described above, in the imaging data acquisition process, spatial variation of a main magnetic field (B0) and linearity of a gradient in the layer selection direction have an influence on generation of a high-brightness signal. As shown in FIG. 4, for one scanning layer surface, only a star-shaped intensity region in the scanning layer surface affects image data of the scanning layer surface, and a star-shaped intensity region located in another scanning layer surface does not affect the image data of the scanning layer surface. Therefore, as shown in FIG. 5, the star-shaped intensity region in the scanning layer surface may be used as a saturated subject of the scanning layer surface. Since the star-shaped intensity region within the scanning layer surface has a limited resonance frequency bandwidth, performing signal saturation based on the scanning layer surface can ensure a saturation effect and can reduce the difficulty of hardware implementation.

In some embodiments, a position of the saturation band in the current scanning layer surface is determined based on a position of the current scanning layer surface and a position of the region of interest. In other words, the saturation band in the current scanning layer surface is located only within the current scanning layer surface, including a region outside the region of interest within the current scanning layer surface.

In some embodiments, the first pulse sequence executed in step 201 includes a saturation pulse and a first gradient pulse applied along with the saturation pulse. To be specific, the saturation pulse coincides with the first gradient pulse in time domain. The first gradient pulse includes a first layer selection gradient pulse in a layer selection direction and a gradient pulse in another direction. The amplitude of the first layer selection gradient pulse is related to the position of the current scanning layer surface, and the amplitude of the gradient pulse in the other direction is related to the position of the saturation band in the current scanning layer surface.

In other words, the position of the saturation band in the current scanning layer surface is determined jointly by the first layer selection gradient pulse and one or a plurality of other gradient pulses in the other direction. As such, the saturation band within the current scanning layer surface can be selected pertinently, implementing accurate selection of the saturation band.

In some embodiments, the first layer selection gradient pulse and the gradient pulse in the other direction are applied simultaneously. For example, a start time of the first layer selection gradient pulse is the same as a start time of the gradient pulse in the another direction, and an end time of the first layer selection gradient pulse is the same as an end time of the gradient pulse in the other direction. As such, the saturation band can be selected within the scanning layer surface while the current scanning layer surface is selected, thereby ensuring accuracy of the position of the saturation band.

In some embodiments, the second pulse sequence executed in step 202 includes an excitation pulse and a second gradient pulse applied along with the excitation pulse. To be specific, the excitation pulse coincides with the second gradient pulse in time domain. The second gradient pulse includes a second layer selection gradient pulse in the layer selection direction, a second phase encoding gradient pulse in a phase encoding direction, and a second frequency encoding gradient pulse in a frequency encoding direction.

The second gradient pulse may be determined based on a preset scanning protocol, and may be a pulse in various forms. For example, the second gradient pulse may be a gradient echo (GRE) pulse sequence, a fast spin echo (FSE) pulse sequence, a fast balanced steady-state free precession (bSSFP) sequence, etc., which is not specifically limited in the embodiments of the present application.

In some embodiments, the first layer selection gradient pulse in the first pulse sequence and the second layer selection gradient pulse in the second pulse sequence have the same amplitude. This can ensure that the scanning layer surface on which the saturation band for signal saturation is located in step 201 and the scanning layer surface on which the region of interest for data acquisition is located in step 202 are the same scanning layer surface. As such, signal saturation can be reliably performed for the current scanning layer surface, and an Annefact artifact of the current scanning layer surface can be reliably suppressed.

In some embodiments, the amplitude of the gradient pulse in the other direction in the first pulse sequence is related to the position of the saturation band. For example, a larger amplitude of the gradient pulse leads to a steeper spatial variation of the magnetic field, and an increased spatial difference of a proton precession frequency. This means that under the action of the same saturation pulse, the saturation band moves to a position with lower or higher magnetic field strength in a direction of a gradient field change, specifically depending on a direction and polarity of the gradient. In addition, the width of the saturation band may be narrowed due to an increased frequency difference, because at a steeper gradient, only a proton precession frequency corresponding to a position with a narrower range can meet a frequency requirement of the saturation band.

A smaller amplitude of the gradient pulse indicates a smoother spatial variation of the magnetic field, and a decreased spatial difference of a proton precession frequency. The saturation band moves in an opposite direction, that is, moves to a position with magnetic field strength being closer to a center value in the direction of the gradient field change. In addition, the width of the saturation band may be widened because proton precession frequencies of more positions can fall within the frequency range of the saturation band.

In some embodiments, the gradient pulse in the other direction in the first pulse sequence may include at least one of a first phase encoding gradient pulse in a phase encoding direction and a first frequency encoding gradient pulse in a frequency encoding direction.

A gradient pulse in a specific direction that is specifically included in the gradient pulse in the other direction may be determined based on a mapping relationship between a main magnetic field direction of the magnetic resonance imaging system and each of the phase encoding direction and the frequency encoding direction.

For example, when the main magnetic field direction coincides with the phase encoding direction, that is, the main magnetic field direction is parallel to the phase encoding direction, the gradient pulse in the other direction includes a first phase encoding gradient pulse in the phase encoding direction, and the first phase encoding gradient pulse and the first layer selection gradient pulse are applied simultaneously.

For example, when the main magnetic field direction coincides with the frequency encoding direction, that is, the main magnetic field direction is parallel to the frequency encoding direction, the gradient pulse in the other direction includes a first frequency encoding gradient pulse in the frequency encoding direction, and the first frequency encoding gradient pulse and the first layer selection gradient pulse are applied simultaneously.

For example, when the main magnetic field direction includes a component of the phase encoding direction and a component of the frequency encoding direction, the gradient pulse in the other direction includes a first phase encoding gradient pulse in the phase encoding direction and a first frequency encoding gradient pulse in the frequency encoding direction, and the first phase encoding gradient pulse, the first frequency encoding gradient pulse, and the first layer selection gradient pulse are applied simultaneously.

In some embodiments, a radio frequency of the saturation pulse may be determined based on the first layer selection gradient pulse and the gradient pulse in the other direction. As such, the radio frequency of the saturation pulse can be adjusted corresponding to the saturation band that is determined jointly by the first layer selection gradient pulse and the gradient pulse in the other direction, thereby helping reliably saturate a signal corresponding to the saturation band.

For example, the radio frequency of the saturation pulse is related to the position of the scanning layer surface determined by the first layer selection gradient pulse and the position of the saturation band determined by the gradient pulse in the other direction. In other words, the radio frequency of the saturation pulse is related to the position of the scanning layer surface and the position of the saturation band within the scanning layer surface, so that the signal corresponding to the saturation band can be saturated pertinently and reliably.

In some embodiments, there is a functional relationship between the radio frequency of the saturation pulse and each of the position of the scanning layer surface and the position of the saturation band within the scanning layer surface. The functional relationship may be a linear relationship, so that the radio frequency of the saturation pulse can be determined in a simple manner. The present application is not limited thereto, and the function may alternatively be a non-linear relationship, etc.

The following describes an imaging method in the present application by way of example with reference to specific accompanying drawings.

The magnetic resonance imaging system has three physical axes (an X physical axis, a Y physical axis, and a Z physical axis) perpendicular to each other, wherein a Z physical axis direction is defined as a main magnetic field direction, an X physical axis direction is defined as a direction perpendicular to the main magnetic field direction in a horizontal plane, and a Y physical axis direction is defined as a direction perpendicular to the Z physical axis direction and the X physical axis direction.

The magnetic resonance imaging system has three logical axes (an X logical axis, a Y logical axis, and a Z logical axis) perpendicular to each other, wherein a Z logical axis direction is defined as a layer selection direction, an X logical axis direction is defined as a frequency encoding direction, and a Y logical axis direction is defined as a phase encoding direction.

Taking sagittal plane scanning and the Y logical axis direction along the physical axis Z as an example, in this case, the X logical axis is aligned or coincides with the Y physical axis, the Y logical axis is aligned or coincides with the Z physical axis, and the Z logical axis is aligned or coincides with the X physical axis.

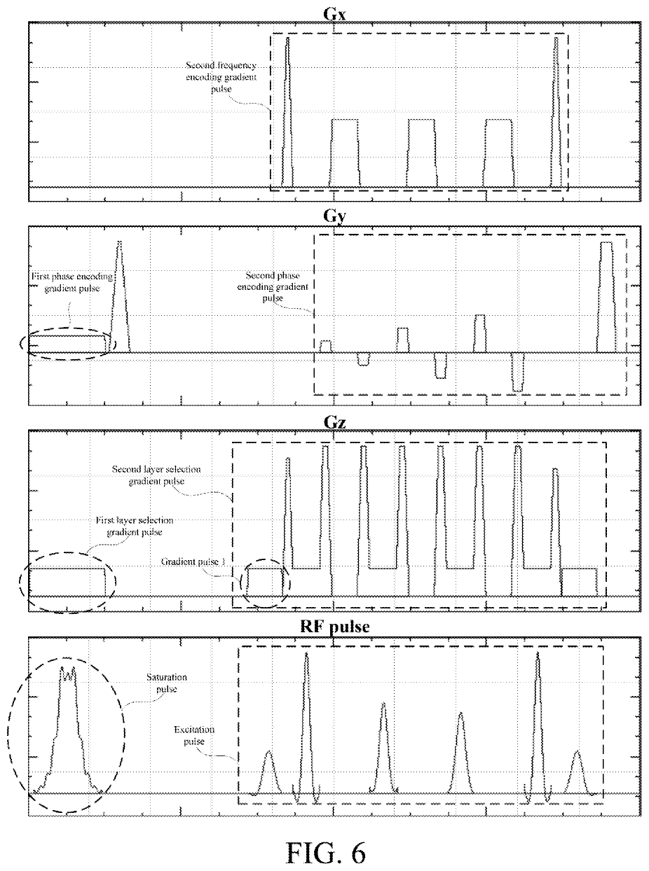

FIG. 6 is a schematic diagram of a first pulse sequence and a second pulse sequence according to an embodiment of the present application. As shown in FIG. 6, Gx is a frequency encoding gradient, Gy is a phase encoding gradient, Gz is a layer selection gradient, and RF pulse is a radio frequency pulse, which includes a saturation pulse and an excitation pulse.

The first pulse sequence is used to saturate a signal corresponding to a saturation band in a current scanning layer surface of a scanned subject. As shown in FIG. 6, the first pulse sequence includes a saturation pulse, and a first layer selection gradient pulse and a first phase encoding gradient pulse that are applied simultaneously with the saturation pulse. Since the main magnetic field direction (the Z physical axis direction) is the same as the phase encoding direction (the Y logical axis direction), the main magnetic field direction has a projection only in the phase encoding direction and has no projection in the frequency encoding direction. Therefore, when signal saturation is performed, the phase encoding gradient pulse is applied simultaneously with the first layer selection gradient pulse.

The second pulse sequence is used to acquire magnetic resonance imaging data from a region of interest of the current scanning layer surface of the scanned subject. As shown in FIG. 6, the second pulse sequence includes an excitation pulse, and a second layer selection gradient pulse, a second phase encoding gradient pulse, and a second frequency encoding gradient pulse that are applied simultaneously with the excitation pulse.

As shown in FIG. 6, the amplitude of the first layer selection gradient pulse is the same as the amplitude of a gradient pulse 1 of the second layer selection gradient pulse for determining a position of the current scanning layer surface. This can ensure that the scanning layer surface on which signal saturation processing is currently performed and the scanning layer surface on which magnetic resonance imaging data is to be acquired are the same scanning layer surface, thereby preventing a high-brightness signal in an Annefact source region from being involved and suppressing an Annefact artifact when magnetic resonance imaging data is acquired on the scanning layer surface.

The amplitude of the second layer selection gradient pulse is determined based on a position of a scanning layer surface determined by the first layer selection gradient pulse and a position of an FOV in the scanning layer surface. The amplitude of the second layer selection gradient pulse may be determined in the following manner: determining a position of a scanning layer surface based on the first layer selection gradient pulse; determining a position of a saturation band of the scanning layer surface based on the position of the scanning layer surface and a position of an FOV in the scanning layer surface; and determining the amplitude of the second layer selection gradient pulse based on the position of the saturation band of the scanning layer surface. The present application is not limited thereto, and the amplitude of the second layer selection gradient pulse may alternatively be determined in another manner.

A frequency of the saturation pulse may be determined based on the position of the current scanning layer surface and the position of the saturation band in the current scanning layer surface. Compared with a conventional manner of applying a saturation band, the saturation pulse correspondingly has a smaller bandwidth and a smaller flip angle.

Although the above description is provided in a manner of applying a saturation band based on a single scanning layer surface, the present application is not limited thereto. The saturation band may alternatively be applied based on more than one scanning layer surface, wherein the number of scanning layer surfaces on which the saturation band is applied simultaneously may be less than the number of scanning layer surfaces included in the entire range to be scanned. As such, signal saturation can be reliably performed, hardware implementation is facilitated, a scanning time can be shortened, and scanning efficiency can be improved.

As shown in FIG. 3 to FIG. 5, signal saturation may be performed on a star-shaped intensity region in an S direction of the S-I direction. FIG. 6 shows a first pulse sequence for performing signal saturation on the star-shaped intensity region in the S direction. The present application is not limited thereto, and alternatively, signal saturation may be performed on a star-shaped intensity region in an I direction of the S-I direction, or signal saturation may be performed on star-shaped intensity regions in both the S direction and the I direction. When signal saturation is performed on the star-shaped intensity regions in both the S direction and the I direction, a first pulse sequence that is used to saturate the star-shaped intensity region in the I direction may be added after the first pulse sequence shown in FIG. 6, or a first pulse sequence capable of simultaneously saturating the star-shaped intensity regions in the S direction and the I direction may be applied, which is not specifically limited in the present application.

FIG. 6 shows a specific example of the first pulse sequence and the second pulse sequence in an orthoaxial scanning scenario (a non-oblique scenario). The imaging method in the embodiments of the present application is also applicable to an oblique scanning scenario (an oblique scenario). In the oblique scanning scenario, the logical axis-based coordinate system is rotated by a specific angle relative to the physical axis-based coordinate system. In this case, the logical axis-based coordinate system can be aligned with the physical axis-based coordinate system by means of coordinate system conversion, for example, by using a rotation matrix (rotation matrix), and the first pulse sequence and the second pulse sequence are determined in the aforementioned manner.

In some embodiments, the magnetic resonance imaging system executing the first pulse sequence may refer to determining control parameters of a related unit or component based on the first pulse sequence, and correspondingly, the magnetic resonance imaging system executing the second pulse sequence may refer to determining control parameters of a related unit or component based on the second pulse sequence. For example, in the magnetic resonance imaging system, the scanning unit executes the first pulse sequence and/or the second pulse sequence, for example, determines parameters such as a current of at least one of a gradient coil, an RF body coil, and an RF surface coil based on the first pulse sequence and/or the second pulse sequence.

In some embodiments, the magnetic resonance imaging system executing the first pulse sequence and the second pulse sequence may mean that the magnetic resonance imaging system executes a pulse sequence for imaging a scanned subject, the pulse sequence including the first pulse sequence and the second pulse sequence.

It should be noted that the above figures merely schematically illustrate the embodiments of the present application, but the present application is not limited thereto. For example, the order of execution between operations may be appropriately adjusted. In addition, some other operations may be added or some operations may be omitted. Those skilled in the art can make appropriate variations according to the above content, rather than being limited by the disclosure of the foregoing accompanying drawings.

According to the aforementioned embodiment, the magnetic resonance imaging system executes a first pulse sequence that is used to saturate a signal corresponding to a saturation band in a current scanning layer surface, and then executes a second pulse sequence that is used to acquire magnetic resonance imaging data from a region of interest of the current scanning layer surface. In other words, only the signal corresponding to the saturation band in the current scanning layer surface is saturated before the magnetic resonance imaging data of the region of interest is acquired. Compared with performing uniform signal saturation for all scanning layer surfaces, the range of a saturation band in a single scanning layer surface is smaller, and a signal corresponding to the saturation band has a limited frequency component, so that requirements for a bandwidth and a flip angle of a saturation pulse can be reduced, thereby reliably preventing an Annefact artifact and facilitating hardware implementation.

Embodiments of the present application further provide a magnetic resonance imaging system. The configuration of the magnetic resonance imaging system is as shown in FIG. 1, and similarities are not repeated here.

In some embodiments, a difference from the aforementioned magnetic resonance imaging system in FIG. 1 lies in that the controller 130 is configured to control a scanning unit to execute the aforementioned imaging method, that is, the controller controls the scanning unit to execute a first pulse sequence, the first pulse sequence being used to saturate a signal corresponding to a saturation band in a current scanning layer surface; and the controller controls the scanning unit to execute a second pulse sequence, the second pulse sequence being used to acquire magnetic resonance imaging data from a region of interest of the current scanning layer surface.

In some embodiments, a position of the saturation band in the current scanning layer surface is determined based on a position of the current scanning layer surface and a position of the region of interest.

In some embodiments, the first pulse sequence includes a saturation pulse and a first gradient pulse applied along with the saturation pulse, and the first gradient pulse includes a first layer selection gradient pulse in a layer selection direction and a gradient pulse in another direction, wherein the amplitude of the first layer selection gradient pulse is related to the position of the current scanning layer surface, and the amplitude of the gradient pulse in the other direction is related to the position of the saturation band in the current scanning layer surface.

In some embodiments, the first layer selection gradient pulse and the gradient pulse in the other direction are applied simultaneously.

In some embodiments, the second pulse sequence includes an excitation pulse and a second gradient pulse applied along with the excitation pulse, the second gradient pulse including a second layer selection gradient pulse in the layer selection direction, a second phase encoding gradient pulse in a phase encoding direction, and a second frequency encoding gradient pulse in a frequency encoding direction, and the first layer selection gradient pulse and the second layer selection gradient pulse having the same amplitude.

In some embodiments, the gradient pulse in the other direction includes at least one of a first phase encoding gradient pulse in a phase encoding direction and a first frequency encoding gradient pulse in a frequency encoding direction.

In some embodiments, the gradient pulse in the other direction is determined based on a mapping relationship between a main magnetic field direction of the magnetic resonance imaging system and each of the phase encoding direction and the frequency encoding direction.

In some embodiments, when the main magnetic field direction is parallel to the phase encoding direction, the gradient pulse in the other direction includes the first phase encoding gradient pulse applied simultaneously with the first layer selection gradient pulse.

In some embodiments, a radio frequency of the saturation pulse is determined based on the first layer selection gradient pulse and the gradient pulse in the other direction.

In some embodiments, the controller 130 (which may also be a processor) includes a computer processor and a storage medium, the storage medium having recorded thereon a predetermined data processing program to be executed by the computer processor. For example, the storage medium may store a program used to implement scanning processing (e.g., including waveform design/conversion, etc.), image reconstruction, image processing, etc. For example, the storage medium may store a program used to implement the scanning sequence adjusting method for a magnetic resonance imaging system or the magnetic resonance imaging method according to the embodiments of the present application. The specific implementations thereof are as described above, and will not be repeated here.

The described storage medium may include, for example, a ROM, a floppy disk, a hard disk, an optical disk, a magneto-optical disk, a CD-ROM, or a non-volatile memory card.

According to the aforementioned embodiment, the magnetic resonance imaging system executes a first pulse sequence that is used to saturate a signal corresponding to a saturation band in a current scanning layer surface, and then executes a second pulse sequence that is used to acquire magnetic resonance imaging data from a region of interest of the current scanning layer surface. In other words, only the signal corresponding to the saturation band in the current scanning layer surface is saturated before the magnetic resonance imaging data of the region of interest is acquired. Compared with performing uniform signal saturation for all scanning layer surfaces, the range of a saturation band in a single scanning layer surface is smaller, and a signal corresponding to the saturation band has a limited frequency component, so that requirements for a bandwidth and a flip angle of a saturation pulse can be reduced, thereby reliably preventing an Annefact artifact and facilitating hardware implementation.

The embodiments of the present application further provide a computer-readable program, wherein the program, when executed in an MRI system, causes a computer to execute, in the MRI system, the method according to the aforementioned embodiments.

The embodiments of the present application further provide a storage medium having a computer-readable program stored therein, wherein the computer-readable program causes a computer to execute, in an MRI system, the method according to the aforementioned embodiments.

The embodiments of the present application further provide a computer program product including at least a computer program, wherein the computer program, when executed by a processor, causes an MRI system to execute the method according to the aforementioned embodiments.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a disk, an optical disk, a DVD, a flash memory, etc.

The method/apparatus described in view of the embodiments of the present application may be directly embodied as hardware, a software module executed by a processor, or a combination of the two. For example, one or more of the functional block diagrams and/or one or more combinations of the functional block diagrams shown in the drawings may correspond to either respective software modules or respective hardware modules of a computer program flow. The foregoing software modules may respectively correspond to the steps shown in the figures. The foregoing hardware modules can be implemented, for example, by firming the software modules using a field-programmable gate array (FPGA).

The software modules may be located in a RAM, a flash memory, a ROM, an EPROM, an EEPROM, a register, a hard disk, a portable storage disk, a CD-ROM, or any other form of storage medium known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, the software modules can be stored in the MEGA-SIM card or the large-capacity flash memory apparatus.

One or more of the functional blocks and/or one or more combinations of the functional blocks shown in the accompanying drawings may be implemented as a general-purpose processor, a digital signal processor (DSP), an application-specific integrated circuit (ASIC), a field-programmable gate array (FPGA) or other programmable logic devices, discrete gate or transistor logic devices, a discrete hardware assembly, or any appropriate combination thereof for executing the functions described in the present application. The one or more functional blocks and/or the one or more combinations of the functional blocks shown in the accompanying drawings may also be implemented as a combination of computing devices, such as a combination of a DSP and a microprocessor, multiple microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. An imaging method for a magnetic resonance imaging system, comprising:
executing a first pulse sequence, wherein the first pulse sequence is used to saturate a signal corresponding to a saturation band in a current scanning layer surface; and
executing a second pulse sequence, wherein the second pulse sequence is used to acquire magnetic resonance imaging data from a region of interest of the current scanning layer surface.

2. The method according to claim 1, wherein,
a position of the saturation band in the current scanning layer surface is determined based on a position of the current scanning layer surface and a position of the region of interest.

3. The method according to claim 1, wherein,
the first pulse sequence comprises a saturation pulse and a first gradient pulse applied along with the saturation pulse, and the first gradient pulse comprises a first layer selection gradient pulse in a layer selection direction and a gradient pulse in another direction,
wherein the amplitude of the first layer selection gradient pulse is related to the position of the current scanning layer surface, and the amplitude of the gradient pulse in the other direction is related to the position of the saturation band in the current scanning layer surface.

4. The method according to claim 3, wherein,
the first layer selection gradient pulse and the gradient pulse in the other direction are applied simultaneously.

5. The method according to claim 3, wherein,
the second pulse sequence comprises an excitation pulse and a second gradient pulse applied along with the excitation pulse, the second gradient pulse comprises a second layer selection gradient pulse in the layer selection direction, a second phase encoding gradient pulse in a phase encoding direction, and a second frequency encoding gradient pulse in a frequency encoding direction, and
the first layer selection gradient pulse and the second layer selection gradient pulse have the same amplitude.

6. The method according to claim 3, wherein,
the gradient pulse in the other direction comprises at least one of a first phase encoding gradient pulse in a phase encoding direction and a first frequency encoding gradient pulse in a frequency encoding direction.

7. The method according to claim 6, wherein,
the gradient pulse in the other direction is determined based on a mapping relationship between a main magnetic field direction of the magnetic resonance imaging system and each of the phase encoding direction and the frequency encoding direction.

8. The method according to claim 7, wherein,
when the main magnetic field direction is parallel to the phase encoding direction, the gradient pulse in the other direction comprises the first phase encoding gradient pulse applied simultaneously with the first layer selection gradient pulse.

9. The method according to claim 3, wherein,
a radio frequency of the saturation pulse is determined based on the first layer selection gradient pulse and the gradient pulse in the other direction.
